(19) United States
(12) Patent Application Publication
(10) Pub. No.: US 2011/0216585 A1
(43) Pub. Date: Sep. 8, 2011

(54) METAL CONTAINING MATERIALS

(75) Inventor: Jaydeb Goswami, Boise, ID (US)

(73) Assignee: Micron Technology, Inc.

(21) Appl. No.: 12/717,535

(22) Filed: Mar. 4, 2010

(51) Int. Cl. G11C 16/04; C01B 21/06; C01B 21/076; H01L 21/336; H01L 29/788

(52) U.S. Cl. 365/185.01; 423/409; 423/411; 438/591; 257/316; 257/E29.3; 257/E21.422

(57) ABSTRACT

Metal containing materials and methods of forming the same are disclosed. One such method includes substantially concurrently feeding a flow of precursor gas containing a metal of a metal containing material and a flow of source gas containing a reducing agent so that the precursor gas and the source gas react to form a thickness of the metal containing material. The flow of precursor gas is discontinued, and while the flow of precursor gas is discontinued, the flow of source gas continues to be fed to contact the thickness of the metal containing material.

### FIELD

The present disclosure relates generally to metal containing materials and their formation, and, in particular, the present disclosure relates to metal containing materials formed from a metal-containing precursor gas and a source gas.

### BACKGROUND

Metal containing materials, e.g., metal nitrides, such as tantalum nitrides, tungsten nitrides, titanium nitrides, etc., are sometimes used as control gates in integrated circuit components, such as non-volatile memory cells of flash memory devices, control gates for select gates, e.g., in memory arrays, control gates of transistors, e.g., field effect transistors, etc. For example, a non-volatile memory cell, e.g., of a flash memory, such as a NAND flash memory, may include a one-transistor memory cell having a control gate including a metal containing material. Changes in threshold voltage of the cells, through programming (which is sometimes referred to as writing) of charge storage nodes (e.g., floating gates or charge traps) or other physical phenomena (e.g., phase change, resistance change, or polarization), determine the data value of each cell. Common uses for flash memory include personal computers, personal digital assistants (PDAs), digital cameras, digital media players, cellular telephones, and removable memory modules.

Metal containing materials (e.g., metal containing films) are sometimes formed on a surface of a material, such as a conductor, dielectric, semiconductor, etc., using chemical vapor deposition (CVD) or physical vapor deposition (PVD) techniques. For example, a chemical vapor deposition technique may involve depositing a thickness of a metal containing material as a result of chemical reactions between various gasses. These gasses are fed to contact the surface of the material on which the thickness of metal containing material is to be formed. For example, the gases may be fed into a processing area, such as a reactor, that contains the material on which the thickness of metal containing material is to be deposited. In general, the reactions involve a metal containing precursor gas to supply the metal ion and a source gas to supply the reducing agent.

The gasses subsequently react to form the thickness of metal containing material over the surface. For example, depositing a thickness of a metal containing material (e.g., a metal nitride) may involve feeding a metal containing precursor gas, such as a tantalum, titanium, or tungsten containing precursor, and a nitrogen containing source gas, such as ammonia (NH₃), to contact the surface of the material so that the metal containing precursor gas and the nitrogen source gas react to form the thickness of metal nitride on the surface.

FIG. 1 is an example of a chemical vapor deposition technique of the prior art for forming a thickness of metal containing material, e.g., a thickness of metal nitride, such as a thickness of tantalum nitride. Flows of tantalum containing precursor gas, e.g., (tert-amylimino)tris(dimethylamino)tantalum (TAIMATA®), and nitrogen containing source gas, e.g., ammonia gas, are fed to contact a surface so that the tantalum containing precursor gas and the ammonia gas react to form a thickness of tantalum nitride on the surface. In the example of FIG. 1, a pulse 110 of metal (e.g., tantalum) containing precursor flow and a pulse 120 of source (e.g., ammonia) gas flow are substantially concurrent (e.g., concurrent) and are of substantially equal (e.g., equal) time duration. The metal containing precursor gas flow and source gas flow are typically fed to the surface until the thickness of metal containing material is at a particular (e.g., predetermined) thickness.

One problem with the technique of FIG. 1 is that a relatively large amount of oxygen, e.g., from the process area or ambient, can be incorporated into the thickness of metal containing material (e.g., the tantalum nitride), thereby reducing the density of the metal containing material and increasing the resistivity of the thickness of metal containing material. This can alter the retention and program/erase characteristics of a memory cell when the thickness of metal containing material is used as a control gate for the memory cell. In addition, some metal containing precursors, such as some tantalum containing precursors, e.g., (tert-amylimino)tris(dimethylamino)tantalum (TAIMATA®), contain carbon that can also be deposited as part of the thickness of metal containing material, further increasing the resistivity of the thickness of metal containing material and further altering the retention and program/erase characteristics of the memory cell when the thickness of metal containing material is used as a control gate for the memory cell.

For the reasons stated above, and for other reasons stated below which will become apparent to those skilled in the art upon reading and understanding the present specification, there is a need in the art for alternative methods for forming metal containing materials, such as metal nitride films.

### BRIEF DESCRIPTION OF THE DRAWINGS

FIG. 1 is an example of a chemical vapor deposition technique of the prior art for forming a metal containing material.

FIG. 2 is a simplified block diagram of a memory system, according to an embodiment.

FIG. 3 is a schematic of a NAND memory array, according to another embodiment.

FIG. 4 illustrates a cross-sectional view of a non-volatile memory cell, according to another embodiment.

FIG. 5 illustrates a cross-sectional view of another non-volatile memory cell, according to another embodiment.

FIG. 6 provides an example of the flows involved in forming a metal containing material, according to another embodiment.

FIGS. 7A-7B are cross-sectional views during different stages of a processing cycle for forming metal containing material, according to another embodiment.

FIGS. 7C-7D are cross-sectional views during different stages of another processing cycle for forming additional metal containing material.

FIG. 8A illustrates x-ray photoelectron spectroscopy (XPS) concentration profiles for tantalum nitride formed in accordance with embodiments of the present disclosure.

FIG. 8B illustrates x-ray photoelectron spectroscopy (XPS) concentration profiles for tantalum nitride formed in accordance with the prior art.

### DETAILED DESCRIPTION

In the following detailed description, reference is made to the accompanying drawings that form a part hereof, and in which is shown, by way of illustration, specific embodiments. In the drawings, like numerals describe substantially similar components throughout the several views. Other embodiments may be utilized and structural, logical, chemical and electrical changes may be made without departing from the scope of the present disclosure. The following detailed description is, therefore, not to be taken in a limiting sense, and the scope of the present disclosure is defined only by the appended claims and equivalents thereof. The term semiconductor can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps may have been utilized to form regions/junctions in the base semiconductor structure, and the term semiconductor can include the underlying layers containing such regions/junctions. The following detailed description is, therefore, not to be taken in a limiting sense, and the scope of the present disclosure is defined only by the appended claims and equivalents thereof.

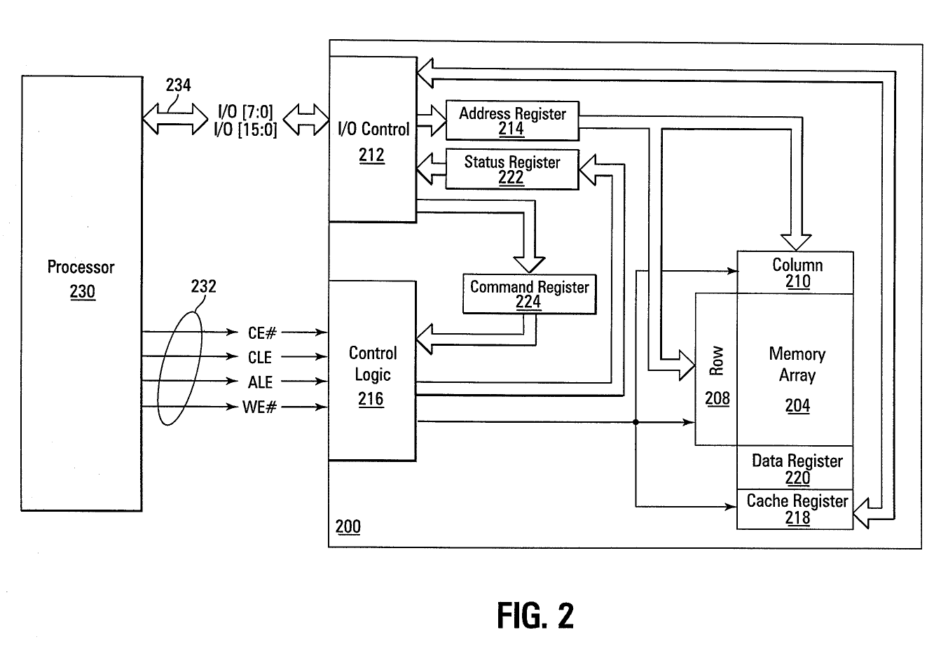

FIG. 2 is a simplified block diagram of a NAND flash memory device 200 in communication with a processor 230 as part of an electronic system, according to an embodiment. The processor 230 may be a memory controller or other external host device. Memory device 200 includes an array of memory cells 204 formed in accordance with embodiments of the disclosure. For example, the memory cells may include metal containing control gates formed in accordance with embodiments of the disclosure. A row decoder 208 and a column decoder 210 are provided to decode address signals. Address signals are received and decoded to access memory array 204.

Memory device 200 also includes input/output (I/O) control circuitry 212 to manage input of commands, addresses and data to the memory device 200 as well as output of data and status information from the memory device 200. An address register 214 is in communication with I/O control circuitry 212, and row decoder 208 and column decoder 210 to latch the address signals prior to decoding. A command register 224 is in communication with I/O control circuitry 212 and control logic 216 to latch incoming commands. Control logic 216 controls access to the memory array 204 in response to the commands and generates status information for the external processor 230. The control logic 216 is in communication with row decoder 208 and column decoder 210 to control the row decoder 208 and column decoder 210 in response to the addresses.

Control logic 216 is also in communication with a cache register 218. Cache register 218 latches data, either incoming or outgoing, as directed by control logic 216 to temporarily store data while the memory array 204 is busy writing or reading, respectively, other data. During a write operation, data is passed from the cache register 218 to data register 220 for transfer to the memory array 204; then new data is latched in the cache register 218 from the I/O control circuitry 212. During a read operation, data is passed from the cache register 218 to the I/O control circuitry 212 for output to the external processor 230; then new data is passed from the data register 220 to the cache register 218. A status register 222 is in communication with I/O control circuitry 212 and control logic 216 to latch the status information for output to the processor 230.

Memory device 200 receives control signals at control logic 216 from processor 230 over a control link 232. The control signals may include at least a chip enable CE#, a command latch enable CLE, an address latch enable ALE, and a write enable WE#. Memory device 200 receives command signals (which represent commands), address signals (which represent addresses), and data signals (which represent data) from processor 230 over a multiplexed input/output (I/O) bus 234 and outputs data to processor 230 over I/O bus 234.

For example, the commands are received over input/output (I/O) pins [7:0] of I/O bus 234 at I/O control circuitry 212 and are written into command register 224. The addresses are received over input/output (I/O) pins [7:0] of bus 134 at I/O control circuitry 212 and are written into address register 214. The data are received over input/output (I/O) pins [7:0] for an 8-bit device or input/output (I/O) pins [15:0] for a 16-bit device at I/O control circuitry 212 and are written into cache register 218. The data are subsequently written into data register 220 for programming memory array 204. For another embodiment, cache register 218 may be omitted, and the data are written directly into data register 220. Data are also output over input/output (I/O) pins [7:0] for an 8-bit device or input/output (I/O) pins [15:0] for a 16-bit device.

It will be appreciated by those skilled in the art that additional circuitry and signals can be provided, and that the memory device of FIG. 2 has been simplified. It should be recognized that the functionality of the various block components described with reference to FIG. 2 may not necessarily be segregated to distinct components or component portions of an integrated circuit device. For example, a single component or component portion of an integrated circuit device could be adapted to perform the functionality of more than one block component of FIG. 2. Alternatively, one or more components or component portions of an integrated circuit device could be combined to perform the functionality of a single block component of FIG. 2.

Additionally, while specific I/O pins are described in accordance with popular conventions for receipt and output of the various signals, it is noted that other combinations or numbers of I/O pins may be used in the various embodiments.

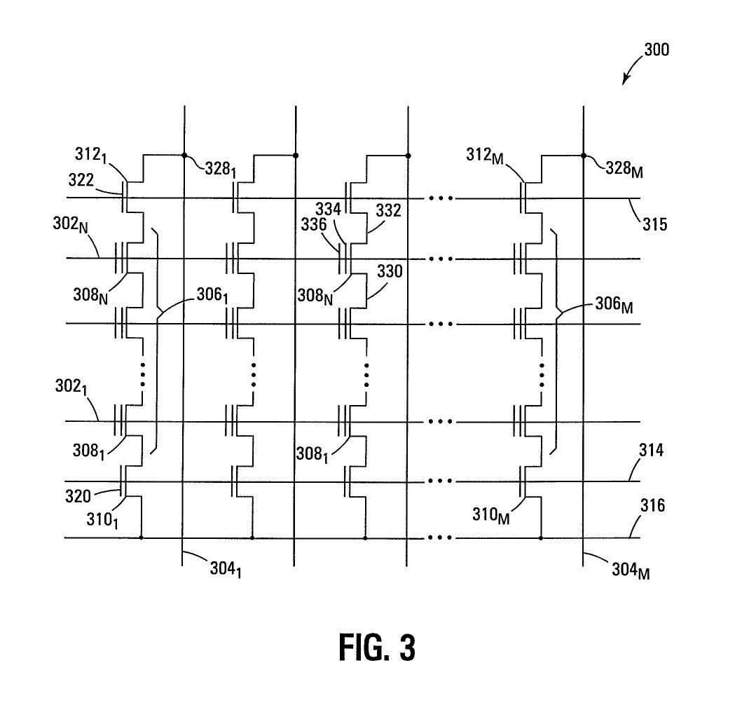

FIG. 3 is a schematic of a NAND memory array 300 as a portion of memory array 204 in accordance with another embodiment. Memory array 300 includes access lines, such as word lines 302₁ to 302_{N}, and intersecting local data lines, such as local bit lines 304₁ to 304_{M}. For ease of addressing in the digital environment, the number of word lines 302 and the number of bit lines 304 are each some power of two, e.g., 256 word lines 302 by 4,096 bit lines 304. The local bit lines 304 are coupled to global bit lines (not shown) in a many-to-one relationship.

Memory array 300 is arranged in rows (each corresponding to a word line 302) and columns. Each column includes a string, such as NAND strings 306₁ to 306_{M}. Each NAND string 306 is coupled to a common source line 316 and includes memory cells 308₁ to 308_{N} (e.g., floating gate transistors) each located at an intersection of a word line 302 and a local bit line 304. The memory cells 308 represent non-volatile memory cells for storage of data. The memory cells 308 of each NAND string 306 are connected in series, source to drain, between a source select line 314 and a drain select line 315.

Source select line 314 includes a source select gate 310, e.g., a field-effect transistor (FET), at each intersection between a NAND string 306 and source select line 314, and drain select line 315 includes a drain select gate 312, e.g., a field-effect transistor (FET), at each intersection between a NAND string 306 and drain select line 315. In this way, the memory cells 308 of each NAND string 306 are connected between a source select gate 310 and a drain select gate 312.

A source of each source select gate 310 is connected to common source line 316 and thus selectively couples its respective NAND string 306 to common source line 316. The drain of each source select gate 310 is connected to the source of the memory cell 308 of the corresponding NAND string 306. For example, the drain of source select gate 310₁ is connected to the source of memory cell 308₁ of the corresponding NAND string 306₁. A control gate 320 of each source select gate 310 is connected to source select line 314. Control gate 320 and source select line 314 may include a metal containing material formed in accordance with the embodiments of the present disclosure.

The drain of each drain select gate 312 is connected to the local bit line 304 for the corresponding NAND string at a drain contact 328. For example, the drain of drain select gate 312₁ is connected to the local bit line 304₁ for the corresponding NAND string 306₁ at drain contact 328₁. The source of each drain select gate 312 is connected to the drain of the last memory cell 308_{N} of the corresponding NAND string 306. For example, the source of drain select gate 312₁ is connected to the drain of memory cell 308_{N} of the corresponding NAND string 306₁. A control gate 322 of each drain select gate 312 is connected to drain select line 315. Control gate 322 and drain select line 315 may include a metal containing material formed in accordance with the embodiments of the present disclosure.

Typical construction of memory cells 308 includes a source 330 and a drain 332, a charge storage node 334 (e.g., a floating gate, charge trap, etc.) that can store a charge that determines a data value of the cell, and a control gate 336, as shown in FIG. 3. Memory cells 308 have their control gates 336 coupled to (and in some cases from) a word line 302. A column of the memory cells 308 is a NAND string 306 coupled to a given local bit line 304. A row of the memory cells 308 are those memory cells commonly coupled to a given word line 302. Control gate 326 and each word line 302 may include a metal containing material formed in accordance with the embodiments of the present disclosure.

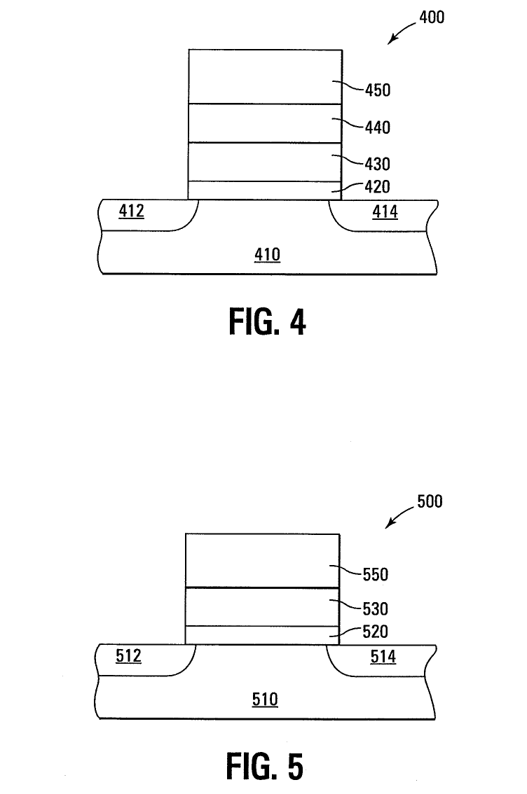

FIG. 4 illustrates a cross-sectional view of a non-volatile memory cell 400 of a memory array, such as NAND memory array 300 of FIG. 3. A dielectric 420, e.g., a tunnel dielectric, is formed over a semiconductor 410 that, in one embodiment, is comprised of p-type silicon. An alternate embodiment may use an n-type material. Dielectric 420 may be formed from an oxide, e.g., silicon oxide, an oxynitride, e.g., silicon oxynitride, etc. Semiconductor 410 has doped regions 412 and 414 that are used as source/drain regions.

A charge storage node 430 is formed over dielectric 420. A dielectric 440, e.g., an interlayer dielectric, may be formed over charge storage node 430 for some embodiments. Charge storage node 430 may be a floating gate formed from a conductor, such as doped polysilicon. For some embodiments the conductor from which the floating gate is formed may contain metal nitride having one or more thicknesses of metal nitride materials. For example, the floating gate may include one or more thicknesses of tantalum nitride, titanium nitride, tungsten nitride, molybdenum nitride, hafnium nitride, zirconium nitride, niobium nitride, etc., formed in accordance with embodiments of the present disclosure. For other embodiments, charge storage node 430 may be a charge trap. For example, the charge trap may be a dielectric, e.g., a high dielectric constant (high-K) dielectric, such as alumina (Al₂O₃) having a K of about 10, with embedded conductive particles (e.g., nano-dots), such as embedded metal particles or embedded nano-crystals (e.g., silicon, germanium, or metal crystals), a silicon rich dielectric, or SiON/Si₃N₄.

Dielectric 440 can be silicon oxide, nitride, oxynitride, oxide-nitride-oxide (ONO), or other dielectric material. For example, dielectric 440 may be a high dielectric constant (high-K) dielectric, such as alumina, hafnia (HfO₂), or zirconia (ZrO₂) with a K of about 20, or praeseodymium oxide (Pr₂O₃) with a K of about 30.

The embedded conductive particles of charge storage node 430 may be used to enhance charge retention for the non-volatile memory cell. For some embodiments, the density range of metal particles in charge storage node 430 is in the range of 5×10¹² to 10×10¹³ with typical particle sizes in the range of 1-3 nanometers and spaced greater than 3 nanometers apart in the high-K dielectric material. Alternate embodiments can use different densities, particle sizes, and spacing.

The metal particles can be of platinum (Pt), gold (Au), cobalt (Co), iridium (Ir), tungsten (W), or some other metal that can provide deep energy electron and hole traps. The metal particle charge trap may be deposited by sputtering or evaporation at relatively low temperatures.

A control gate 450 is formed over dielectric 440. Control gate 450 may contain metal nitride having one or more thicknesses of metal nitride materials. For example, control gate 450 may include one or more thicknesses of a tantalum nitride, titanium nitride, tungsten nitride, molybdenum nitride, hafnium nitride, zirconium nitride, niobium nitride, etc., formed in accordance with embodiments of the present disclosure. Note that control gate 450 may form a portion of an access line, such as a word line, of the memory array, meaning that the word line is formed from one or more thicknesses of metal containing material. Control gate 450 may further include thicknesses of other conductive materials in addition to metal containing materials formed in accordance with embodiments of the disclosure.

FIG. 5 illustrates a cross-sectional view of a non-volatile memory cell 500 of a memory array, such as NAND memory array 300 of FIG. 3. A dielectric 520, e.g., a tunnel dielectric, is formed over a semiconductor 510 that, in one embodiment, is comprised of p-type silicon. An alternate embodiment may use an n-type material. Dielectric 520 may be formed from an oxide, e.g., silicon oxide, an oxynitride, e.g., silicon oxynitride, etc. Semiconductor 510 has doped regions 512 and 514 that are used as source/drain regions.

A charge storage node 530 is formed over dielectric 520. Charge storage node 530 may be a charge trap. For example, the charge trap may be a high dielectric constant (high-K) dielectric, such as alumina (Al₂O₃) having a K of about 10, with embedded conductive particles (e.g., conductive nano-dots), such as embedded metal particles or embedded nano-crystals (e.g., silicon, germanium, or metal crystals), a silicon rich dielectric, or SiON/Si₃N₄. For some embodiments, the density range of metal particles in charge storage node 530 is in the range of 5×10¹² to 10×10¹³ with typical particle sizes in the range of 1-3 nanometers and spaced greater than 3 nanometers apart in the high-K dielectric material. Alternate embodiments can use different densities, particle sizes, and spacing.

The metal particles can be of platinum (Pt), gold (Au), cobalt (Co), iridium (Ir), tungsten (W), or some other metal that can provide deep energy electron and hole traps. The metal particle charge trap may be deposited by sputtering or evaporation at relatively low temperatures.

A control gate 550 is formed over charge storage node 530. Control gate 550 may contain metal nitride having one or more thicknesses of metal nitride materials. For example, control gate 550 may include one or more thicknesses of a tantalum nitride, titanium nitride, tungsten nitride, molybdenum nitride, hafnium nitride, zirconium nitride, niobium nitride, etc., formed in accordance with embodiments of the present disclosure. Note that control gate 550 may form a portion of an access line, such as a word line, of the memory array, meaning that the word line is formed from one or more thicknesses metal containing material. Control gate 550 may further include thicknesses of other conductive materials in addition to metal containing materials formed in accordance with embodiments of the disclosure.

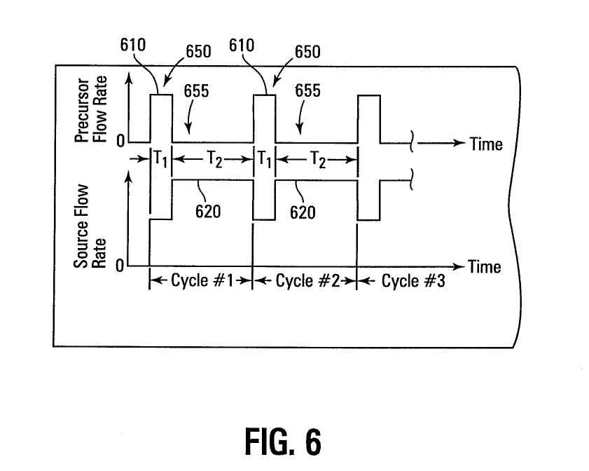

FIG. 6 provides an example of the flows involved in forming a metal containing material (e.g., a metal containing film) over a surface of a material. An example of a metal containing film is a metal nitride containing film, such as a tantalum nitride containing film (e.g., tantalum nitride film), titanium nitride containing film (e.g., titanium nitride film), tungsten nitride containing film (e.g., tungsten nitride film), molybdenum nitride containing film (e.g., molybdenum nitride film), hafnium nitride containing film (e.g., hafnium nitride film), zirconium nitride containing film (e.g., zirconium nitride film), niobium nitride containing film (e.g., niobium nitride film), etc. For example, one or more thicknesses the metal containing material may form at least a portion of floating gate 430 and/or control gate 450 of memory cell 400 (FIG. 4) or control gate 550 of memory cell 500 (FIG. 5). The material over which floating gate 430 is to be formed is dielectric 420; the material over which control gate 450 is to be formed is dielectric 440; and the material over which control gate 550 is to be formed is the material of charge storage node 530.

For other embodiments, one or more thicknesses of the metal containing material may form control gates and other conductors of other integrated circuit components, such as of control gates for select gates, e.g., in memory arrays (such as memory array 300 of FIG. 3), control gates of transistors, e.g., field effect transistors, capacitor electrodes, e.g., top and/or bottom electrodes of a capacitor, etc. For example, a control gate containing a metal containing material may be formed over a gate dielectric, e.g., gate oxide, for some select gates, such as select gates 310 and 312 in FIG. 3.

For some embodiments, a process of forming a thickness of metal containing material over a surface of a material involves concurrently feeding a flow of precursor gas containing the metal of a metal containing material and a flow of a reducing agent containing source gas, e.g., a nitrogen source, such as ammonia, to contact the surface so that the precursor gas and the source gas react to form the thickness of metal containing material over the surface. For example, the flow of precursor gas and the flow of source gas may be fed substantially concurrently (e.g., concurrently) into a process area, such as a reactor chamber, containing the surface of the material so as to contact the surface of the material. Other examples of the source gas include hydrogen, hydrogen mixed with nitrogen, a plasma made from nitrogen and/or hydrogen, and any radicals containing nitrogen and/or hydrogen. Non-limiting examples of such radicals include NH*, NH₂*, H*, H₂*, N*, and N₂*

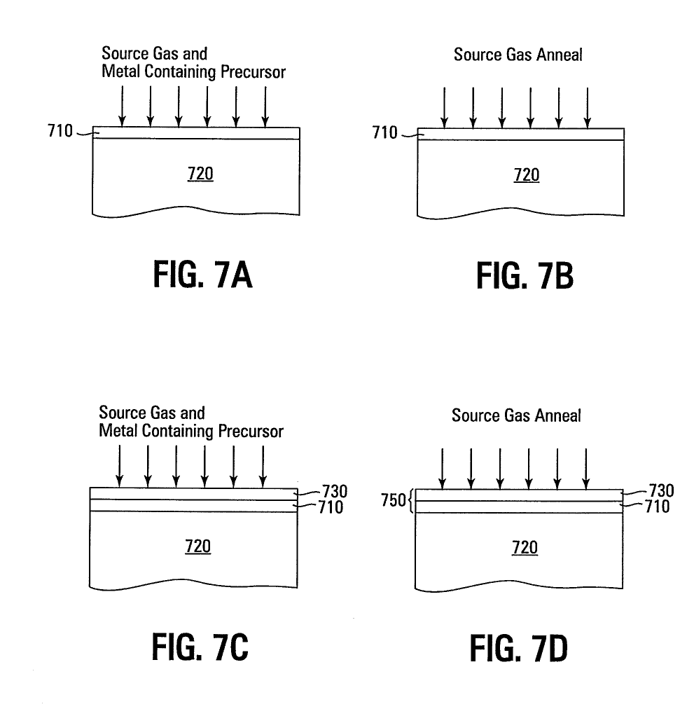

The flow of precursor gas and the flow of source gas, respectively indicated by flow pulses 610 and 620, in FIG. 6, substantially concurrently (e.g., concurrently) flow for a time T₁, e.g., that lies in a range of about 0.1 to about 10.0 seconds. The precursor gas and the source gas react to form a thickness 710 of metal containing material over a surface of a material 720, as shown in FIG. 7A. When the precursor gas source gas have flowed concurrently for the time T₁, the flow of precursor gas is discontinued, but the source gas is allowed to continue to flow in contact with the thickness 710 of metal containing material for an additional time T₂, e.g., of about 10 seconds, as shown in FIGS. 6 and 7B, after the flow of precursor gas is discontinued. For one embodiment, the length of time T₂ is greater than or equal to the length of time T₁. For a further embodiment, the length of time T₂ is greater than twice the length of time T₁.

The flow pulse 610 has duration that is substantially equal (e.g., equal) to the time T₁, and flow pulse 620 has duration that is substantially equal (e.g., equal) to the sum of the times T₁ and T₂. The sum of the times T₁ and T₂ is substantially equal (e.g., equal) to length, e.g., the period, of one processing cycle, such as of processing cycles 1, 2, 3, etc. The time T₁ and the sum of the times T₁ and T₂ can be viewed as elapsed cycle times, starting from the start of each processing cycle. Note that each processing cycle forms a thickness of metal containing material, such as thickness 710 of metal containing material.

As shown in FIG. 6, flow pulses 610 and 620 are concurrent and react to form the thickness 710 of metal containing material during an initial portion of a processing cycle, e.g., having a duration that is substantially equal (e.g., equal) to the time T₁. The flow pulse 610 (e.g., the metal containing precursor flow pulse) is discontinued at an elapsed cycle time that is substantially equal (e.g., equal) to the time T₁, while flow pulse 620 (e.g., the source gas flow pulse) continues for the remaining portion of the flow cycle, e.g., having a duration that is substantially equal (e.g., equal) to the time T₂.

The portion of a processing cycle where the flow of the metal containing precursor is discontinued and the source gas continues to flow may be referred to as a source anneal, e.g., an ammonia anneal (FIGS. 6, 7B, and 7D). For example, each processing cycle may include a reaction portion 650 (FIGS. 6, 7A, and 7C), e.g., having a duration that is substantially equal (e.g., equal) to the time T₁, where the source gas and metal containing precursor are flowing concurrently and are reacting, and an anneal portion 655 (FIGS. 6, 7B, and 7D), e.g., having a duration that is substantially equal (e.g., equal) to the time T₂, where the flow of the metal containing precursor is discontinued and the source gas continues to flow after the flow of the metal containing precursor is discontinued.

For some embodiments, during each processing cycle, the flow rate of source gas may be increased at an elapsed cycle time that is substantially equal (e.g., equal) to the time T₁ (e.g., after the flow of the metal containing precursor is discontinued), as shown in FIG. 6, so that the flow rate of the source gas during an anneal portion 655, i.e., second portion, of a processing cycle is higher than when the source gas and metal containing precursor are concurrently flowing and reacting during a reaction portion 650, i.e., first portion, of the processing cycle. As an example, the flow rate of the source gas during an anneal portion 655 may lie in a range of about 10 sccm to about 1000 sccm; the flow rate of the metal containing precursor during a reaction portion 650 may lie in a range of about 10 to about 500 mg/min; and the flow rate of the source gas during the reaction portion 650 may be about 400 sccm.

For some embodiments, the flow rate of the source gas during an anneal portion 655 may be about 800 sccm. The pressure of a process area in which the processing takes place and which contains material 720 may be about 1-2 Torr, and the temperature of the material 720 on which the metal containing material is to be formed may be about 350° C. This temperature may be maintained for both portions of a processing cycle. Note that for some embodiments, at the end of each processing cycle, e.g., at an elapsed cycle time substantially equal (e.g., equal) to sum of the times T₁ and T₂, the flow rate of source gas may be reduced back to the flow rate that occurs during the reaction portion, in preparation for the next processing cycle, as shown in FIG. 6.

The metal containing precursor gas may be a tantalum containing precursor gas, titanium containing precursor gas, tungsten containing precursor gas, molybdenum containing precursor gas, hafnium containing precursor gas, zirconium containing precursor gas, niobium containing precursor gas, etc. For some embodiments, the metal containing precursor gas may be a metal-organic, containing carbon. For example, the tantalum containing precursor gas may be (tert-amylimino)tris(dimethylamino)tantalum (TAIMATA®), pentakis(dimethylamido)tantalum (PDMAT), Tert-Butylimido-Tris(Diethylamido)tantalum (TBTDET), tert-butylimino tri(ethylmethylamino)tantalum (TBTEMT), etc. Tetrakis(dimethylamido)titanium (TDMAT) is an example of a titanium containing precursor; W(NMe₂)₆ is an example of a tungsten containing precursor; Tetrakis (dimethylamido)molybdenum(IV) is an example of a molybdenum containing precursor; Tetrakis(ethylmethylamino)hafnium is an example of a hafnium containing precursor; Tetrakis(ethylmethylamino)zirconium is an example of a zirconium containing precursor; and Tert-Butylamido-Tris-(Diethylamido)-niobium is an example of a niobium containing precursor. The forgoing examples of metal containing precursors are metal-organics containing carbon.

For some embodiments, processing cycle 2 is performed when the thickness 710 of metal containing material at the end of cycle 1 is less than a particular (e.g., predetermined) thickness. For example, during the reaction portion 650 of processing cycle 2, the source gas and metal containing precursor flow concurrently in contact with the thickness 710 of metal containing material and react to form a thickness 730 of metal containing material over the thickness 710 of metal containing material, as shown in FIG. 7C. When the precursor gas and source gas have flowed concurrently for the time T₁, the flow of precursor gas is discontinued, e.g., at the end of the reaction portion 650 of processing cycle 2 and the start of the anneal portion 655 of processing cycle 2. After the flow of precursor gas is discontinued, the source gas continues to flow during the anneal portion 655 of processing cycle 2 in contact with the thickness 730 of metal containing material, as shown in FIG. 7D.

Additional processing cycles may be performed until the thicknesses of metal containing materials reach the particular thickness. For example, it may take about 10 processing cycles to deposit about 70 Angstroms of tantalum nitride. Note that one or more thickness of metal containing material (e.g., the thickness 710 of metal containing material with the thickness 730 of metal containing material formed thereover) may collectively be referred to as a metal containing material (e.g., a metal containing film) 750 (FIG. 7D).

It is recognized that the thickness of the metal containing film 750 would typically not be measured after each processing cycle. Though in situ measurement methods are known, it would be more common to determine an expected rate of deposition for each processing cycle, e.g., from historical data or theoretical reaction kinetics, and determine an expected number of processing cycles needed to produce the particular thickness.

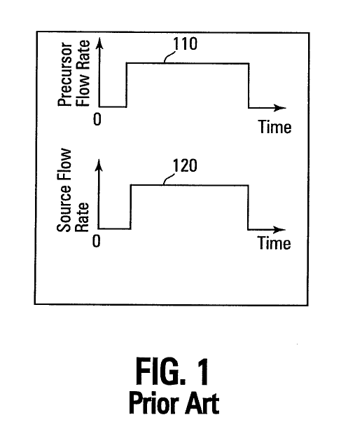

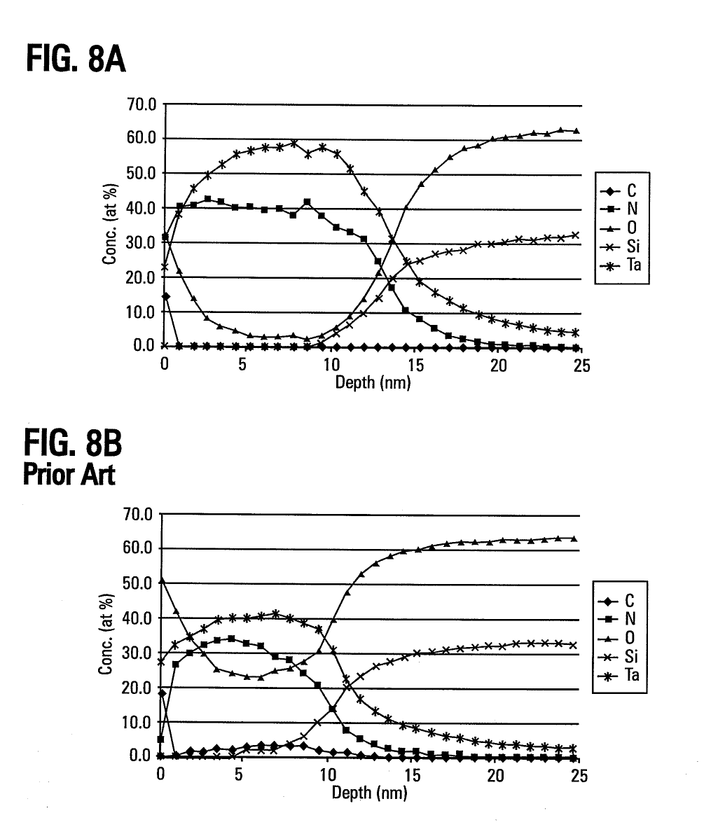

FIG. 8A illustrates x-ray photoelectron spectroscopy (XPS) concentration profiles for a tantalum nitride material formed on silicon oxide in accordance an embodiment of the present disclosure, e.g., the processing of FIG. 6. FIG. 8B illustrates x-ray photoelectron spectroscopy (XPS) concentration profiles for a tantalum nitride material formed on silicon oxide in accordance with a prior art process, e.g., the processing of FIG. 1. For this illustration, the flow rate of the tantalum containing precursor (e.g., TAIMATA®) during flow pulse 110 in FIG. 1 and flow pulse 610 in FIG. 6 were substantially the same. The flow rate of the source gas (e.g., ammonia) during the reaction portions 650 during the processing cycles in FIG. 6 and the flow rate of the source gas (e.g., ammonia) flow during flow pulse 120 in FIG. 1 were substantially the same.

The number of processing cycles in FIG. 6 for this illustration were selected so that the area of the sum of the pulses 610 (e.g., the amount of tantalum containing precursor) summed over the selected number of cycles was substantially equal to the area of pulse 110 (e.g., the amount of tantalum containing precursor) in FIG. 1 so that the amount of fed tantalum precursor was substantially the same for the processes of FIGS. 1 and 6. Similarly, the area of the sum of the portions of the pulses 620 corresponding to the reaction portions 650 (e.g., the amount of ammonia fed concurrently with the tantalum containing precursor) summed over the selected number of cycles was substantially equal to the area of pulse 120 (e.g., the amount of ammonia fed concurrently with the tantalum containing precursor) so that the amount of ammonia gas that was fed concurrently with the tantalum containing precursor was substantially the same for the processes of FIGS. 1 and 6.

The depth in FIGS. 8A and 8B is measured from an upper surface of the tantalum nitride, where a zero depth coincides with the upper surface. A comparison of the profiles reveals that the process of FIG. 6 for this illustration facilitated a reduction in the oxygen content in the tantalum nitride, e.g., about 4 at % at a depth of about 5 nanometers for the process of FIG. 6 versus about 22 at % at a depth of about 5 nanometers for the process of FIG. 1. The process of FIG. 6 for this illustration also substantially eliminated the carbon content in the tantalum nitride material, e.g., about 0 at % at a depth of about 7 nanometers for the process of FIG. 6 versus about 3 at % at a depth of about 7 nanometers for the process of FIG. 1. The reduction in oxygen and carbon reduces the resistivity of the tantalum nitride and is believed to be due, at least in part, to the anneal portion 655 (e.g., ammonia anneal) in each of the process cycles of the process of FIG. 6.

X-ray reflectivity (XRR) concentration measurements performed on the respective tantalum nitride materials revealed that the density of tantalum nitride formed from the process of FIG. 6 was about 22 percent greater than the density of tantalum nitride formed from the process of FIG. 1, e.g., about 10.1 gm/cm³ from the process of FIG. 6 versus about 8.3 gm/cm³ from the process of FIG. 1. The increased density of tantalum nitride in the film reduces the resistivity of the tantalum nitride and is believed to be due, at least in part, to the anneal portion 655 (e.g., ammonia anneal) in each of the process cycles of the process of FIG. 6.

A memory cell having a tantalum nitride containing control gate formed from the process of FIG. 6 was found to have comparable data retention characteristics and improved erase characteristics compared to a memory cell having a tantalum nitride containing control gate formed from the process of FIG. 1.

### CONCLUSION

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments. It is manifestly intended that the embodiments be limited only by the following claims and equivalents thereof.

What is claimed is:

1. A method of forming a metal containing material, comprising:
for a first portion of a processing cycle:
substantially concurrently feeding a flow of a precursor gas containing the metal of the metal containing material and a flow of a source gas containing a reducing agent, and reacting the precursor gas and the source gas to form a thickness of the metal containing material; and
for a second portion of the processing cycle subsequent to the first portion of the processing cycle:
discontinuing the flow of the precursor gas; and
continuing to feed the flow of the source gas to contact the thickness of the metal containing material while not feeding the flow of the precursor gas.

2. The method of claim 1, further comprising increasing a rate of the flow of the source gas for the second portion of the processing cycle.

3. The method of claim 2, wherein increasing the rate of the flow of the source gas for the second portion of the processing cycle occurs at a time that is substantially equal to a time of discontinuing the flow of the precursor gas.

4. The method of claim 1, wherein forming a metal containing material comprises forming a material selected from the group consisting of tantalum nitride, tungsten nitride, molybdenum nitride, hafnium nitride, zirconium nitride, niobium nitride, and titanium nitride.

5. The method of claim 1, wherein feeding a flow of a source gas containing a reducing agent comprises feeding a flow of nitrogen and/or hydrogen, radicals containing nitrogen and/or hydrogen, or plasma made from nitrogen and/or hydrogen.

6. The method of claim 1, wherein the precursor gas contains tantalum, tungsten, titanium, molybdenum, hafnium, zirconium, or niobium and the source gas is ammonia gas.

7. The method of claim 1, further comprising performing more than one processing cycle to increase the thickness of the metal containing material.

8. The method of claim 7, further comprising returning the rate of the flow of the source gas during a first portion of a particular processing cycle to be substantially equal to the rate of the flow of the source gas during a first portion of a previous processing cycle.

9. The method of claim 1, wherein forming a metal containing material comprises forming a metal containing material during formation of a memory cell, wherein the metal containing material forms at least a portion of a control gate and/or a floating gate of the memory cell.

10. The method of claim 1, wherein the first portion of the processing cycle is of a first length of time, the second portion of the processing cycle is of a second length of time, and the processing cycle is of a length of time substantially equal to the first length of time plus the second length of time.

11. The method of claim 10, wherein the second length of time is greater than or equal to the first length of time.

12. The method of claim 11, wherein the second length of time is greater than twice the first length of time.

13. A method of forming a memory cell, comprising:
forming a dielectric over a semiconductor;
forming a gate over the charge storage node, wherein the gate comprises one or more thicknesses of metal containing material, wherein forming a respective thickness of the metal containing material of the one or more thicknesses of the metal containing material comprises:
for a first portion of a processing cycle:
substantially concurrently feeding a flow of a precursor gas containing the metal of the metal containing material and a flow of a source gas containing a reducing agent, and reacting the precursor gas and the source gas to form the respective thickness of the metal containing material; and
for a second portion of the processing cycle subsequent to the first portion of the processing cycle:
discontinuing the flow of the precursor gas; and
continuing to feed the flow of the source gas to contact the respective thickness of the metal containing material while not feeding the flow of the precursor gas.

14. The method of claim 13, further comprising increasing a rate of the flow of the source gas for the second portion of the processing cycle.

15. The method of claim 13, wherein the metal containing material comprises, tantalum nitride, tungsten nitride, or titanium nitride, the precursor gas contains tantalum, tungsten, or titanium, and the source gas is ammonia gas.

16. The method of claim 13, further comprising forming a charge storage node over the dielectric prior to forming the gate, wherein the gate comprises a control gate.

17. The method of claim 13, further comprising:
forming a second dielectric over the gate; and
forming another gate over the second dielectric.

18. The method of claim 13, further comprising forming the gate to comprise one or more thicknesses of a second metal containing material by performing one or more processing cycles using a second precursor gas containing the metal of the second metal containing material.

19. The method of claim 13, further comprising forming the gate to comprise one or more thicknesses of another conductive material.

20. A memory cell, comprising:
a dielectric over a semiconductor;
a gate over the dielectric, the gate comprising one or more thicknesses of metal containing material, wherein a respective thickness of the metal containing material of the one or more thicknesses of the metal containing material is formed using a method comprising:
for a first portion of a processing cycle:
substantially concurrently feeding a flow of a precursor gas containing the metal of the metal containing material and a flow of a source gas containing a reducing agent, and reacting the precursor gas and the source gas to form a thickness of the metal containing material; and
for a second portion of the processing cycle subsequent to the first portion of the processing cycle:
discontinuing the flow of the precursor gas; and
continuing to feed the flow of the source gas to contact the thickness of the metal containing material while not feeding the flow of the precursor gas.

21. The memory cell of claim 20, wherein the method further comprises increasing a rate of the flow of the source gas during the second portion of the processing cycle.

22. The memory cell of claim 20, wherein the metal containing material comprises, tantalum nitride, tungsten nitride, or titanium nitride, the precursor gas contains tantalum, tungsten, or titanium, and the source gas is ammonia gas.

23. The memory cell of claim 20, further comprising a charge storage node between the dielectric and the gate.

24. The memory cell of claim 23, wherein the charge storage node is selected from the group consisting of a dielectric, a high-K dielectric, a high-K dielectric having embedded conductive particles, polysilicon, and a metal containing film.

25. The memory cell of claim 20, wherein the gate comprises a floating gate and further comprising a second dielectric over the floating gate, and a control gate over the second dielectric.

26. The memory cell of claim 20, wherein the gate comprises a control gate and further comprising a charge storage node over the dielectric, wherein the control gate is also over the charge storage node.

27. A memory device, comprising:
an array of memory cells; and
control circuitry configured to access the array of memory cells;
wherein the array of memory cells comprises a plurality of non-volatile memory cells; and
wherein at least one memory cell of the array of memory cells comprises a gate comprising at least one metal containing material formed using a method comprising:
for a first portion of a processing cycle:
substantially concurrently feeding a flow of a precursor gas containing the metal of the metal containing material and a flow of a source gas containing a reducing agent, and reacting the precursor gas and the source gas to form a thickness of the metal containing material; and
for a second portion of the processing cycle subsequent to the first portion of the processing cycle:
discontinuing the flow of the precursor gas; and
continuing to feed the flow of the source gas to contact the thickness of the metal containing material while not feeding the flow of the precursor gas.

28. The memory device of claim 27, wherein the at least one memory cell is capable of changes in threshold voltage through charge storage, phase change or polarization.
